(19) United States
(12) Patent Application Publication
(10) Pub. No.: US 2016/0079462 A1
(43) Pub. Date: Mar. 17, 2016

(54) PACKAGE STRUCTURE OF SOLAR PHOTOVOLTAIC MODULE

(71) Applicant: Industrial Technology Research Institute, Hsinchu (TW)

(72) Inventors: Cheng-Yu Peng, Taoyuan City (TW); Chien-Rong Huang, Hsinchu City (TW); Ray-Chien Lai, Taoyuan City (TW)

(21) Appl. No.: 14/864,906

(22) Filed: Sep. 25, 2015

Related U.S. Application Data
(63) Continuation-in-part of application No. 12/982,878, filed on Dec. 31, 2010, now abandoned.

(30) Foreign Application Priority Data
Dec. 6, 2010 (TW) 99142389

(51) Int. Cl. H01L 31/054; H01L 31/048; H01L 31/049

(52) U.S. Cl. CPC H01L 31/0547; H01L 31/049; H01L 31/048

(57) ABSTRACT

A package structure of solar photovoltaic module is provided. The package structure of solar photovoltaic module includes a transparent substrate, a backsheet disposed opposite to the transparent substrate, a plurality of solar cells between the transparent substrate and the backsheet, several encapsulants sandwiched in between the transparent substrate and the backsheet, and an optical board, wherein the encapsulants encapsulate the solar cells. The optical board is adhered to an outer surface of the backsheet, wherein the optical board has an embossing surface, and the embossing surface is a serrated surface, and a vertex angle of the serrated surface is larger than 60° and less than 150°.

### CROSS-REFERENCE TO RELATED APPLICATION

This application is a continuation-in-part application of and claims the priority benefit of a prior application Ser. No. 12/982,878, filed on Dec. 31, 2010, now pending, which claims the priority benefit of Taiwan application serial no. 99142389, filed on Dec. 6, 2010. The entirety of each of the above-mentioned patent applications is hereby incorporated by reference herein and made a part of this specification.

### TECHNICAL FIELD

The disclosure relates to a package structure of a solar photovoltaic module.

### BACKGROUND

Solar energy is a clean, pollution-free and inexhaustible energy. Therefore, when problems of pollution and shortage of petroleum energy are encountered, how to effectively use the solar energy becomes a focus of attention. Since a solar cell can directly convert the solar energy into electric power, it becomes a development priority of using the solar energy.

A typical package structure of a solar photovoltaic module is as shown in FIG. 1, which includes a glass 100, an adhesive 102, a solar cell 104, an adhesive 106 and a backsheet 108. Such package structure generally has a light loss due to a package loss thereof, so that a power output from the solar cell is reduced. Main causes of the light loss of the solar cell are as follows: 1. reflection loss between external environment (air) and the glass, 2. reflection loss of a surface of the solar cell and the adhesive, and 3. light reflection loss of the backsheet.

Therefore, related industries generally focus on development of module materials and fabrication techniques, for example, an antireflection layer of the solar cell, a glass surface embossing structure of the solar photovoltaic module, etc., they still lack for a design of effectively recycling reflected light from the solar cell and the backsheet.

### SUMMARY

A package structure of a solar photovoltaic module is introduced herein so as to achieve a light trapping effect and further improve a module power.

A package structure of a solar photovoltaic module is introduced herein. The package structure includes a transparent substrate, a backsheet disposed opposite to the transparent substrate, a plurality of solar cells between the transparent substrate and the backsheet, a plurality of encapsulants sandwiched between the transparent substrate and the backsheet and encapsulating the solar cells, and an optical board adhered to an outer surface of the backsheet. The optical board has an embossing surface, the embossing surface is a serrated surface, and a vertex angle of the serrated surface is larger than 60° and less than 150°.

According to the foregoing, in the package structure of the solar photovoltaic module of the disclosure, and an embossing surface is at outer surface of the optical board to enhance luminous flux, so as to improve a module power.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a cross-sectional view of a conventional package structure of a transparent solar photovoltaic module.

FIG. 2 is a cross-sectional view of a package structure of a solar photovoltaic module according to a first exemplary embodiment.

FIGS. 3A-3D are three-dimensional views of structures having various embossing surfaces.

FIG. 4 is a cross-sectional view of a package structure of a solar photovoltaic module according to a second exemplary embodiment.

FIG. 5 is an enlarged diagram of an optical board having an embossing surface of FIG. 4.

FIG. 6A is a cross-sectional view of a package structure of a solar photovoltaic module according to a third exemplary embodiment.

FIG. 6B is a cross-sectional view of another package structure of a solar photovoltaic module according to the third exemplary embodiment.

FIG. 7 is a flowchart illustrating a method of manufacturing a package structure of a solar photovoltaic module according to a fourth embodiment.

FIG. 8 is a cross-section view of a package structure of a solar photovoltaic module of a fifth and sixth experiments.

FIG. 9 is a cross-section view of a package structure of a solar photovoltaic module of a seventh experiment.

FIG. 10 is a cross-section view of a package structure of a solar photovoltaic module of an eighth experiment.

FIG. 11 is a cross-section view of a solar photovoltaic module with an optical board of a ninth experiment.

FIG. 12 is a curve diagram of the luminous flux of the solar photovoltaic module in the ninth experiment.

FIG. 13 is a curve diagram of the luminous flux of the solar photovoltaic module in the tenth experiment.

### DETAILED DESCRIPTION OF DISCLOSED EMBODIMENTS

Following exemplary embodiments with reference of figures are only used for describing the disclosure in detail. However, the disclosure can also be achieved through different implementations, which is not limited to the following embodiments. In the figures referred to herein, sizes and relative sizes of different layers are probably exaggerated for clarity of illustration and are not necessarily drawn to scale.

FIG. 2 is a cross-sectional view of a package structure of a solar photovoltaic module according to a first exemplary embodiment.

Referring to FIG. 2, the package structure of the solar photovoltaic module of the first exemplary embodiment includes a transparent substrate 200, a backsheet 202 disposed opposite to the transparent substrate 200, a plurality of solar cells 204 between the transparent substrate 200 and the backsheet 202, and a first, a second and a third encapsulants 206, 208 and 210 sandwiched by the transparent substrate 200 and the backsheet 202. The solar cells 204 are encapsulated in the encapsulants 206, 208 and 210. In the first exemplary embodiment, an embossing interface 212 exists between the second encapsulant 208 and the third encapsulant 210, and the third encapsulant 210 having the embossing interface 212 is a thermosetting material, for example, ethylene-vinyl acetate copolymer (EVA). An embossing interface can be located between the encapsulants 206, 208 and 210 with same material of EVA by using transfer-printing manufacturing. Moreover, the encapsulants 206, 208 and 210 may be color package materials.

When the solar light is incident to the embossing interface 212, the embossing interface 212 has a light guiding effect and a light trapping effect, so that the light may be reflected to the solar cells 204 for recycling. Moreover, in the first exemplary embodiment, the backsheet 202 may be a transparent material or an opaque material, and when the backsheet 202 is the transparent material, it has a high back transmittance, which is suitable for applying to a transparent solar photovoltaic module.

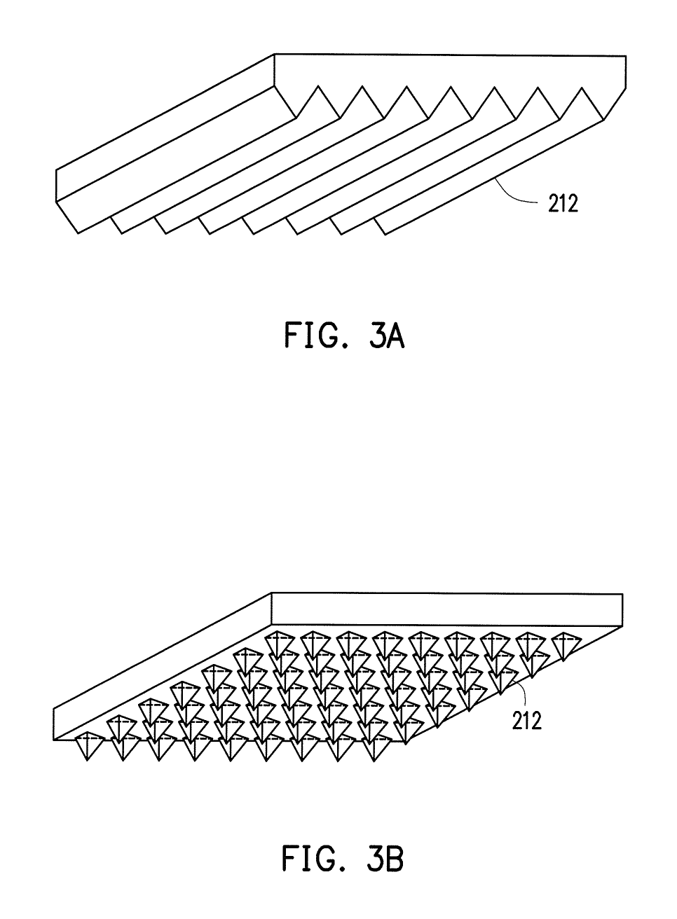

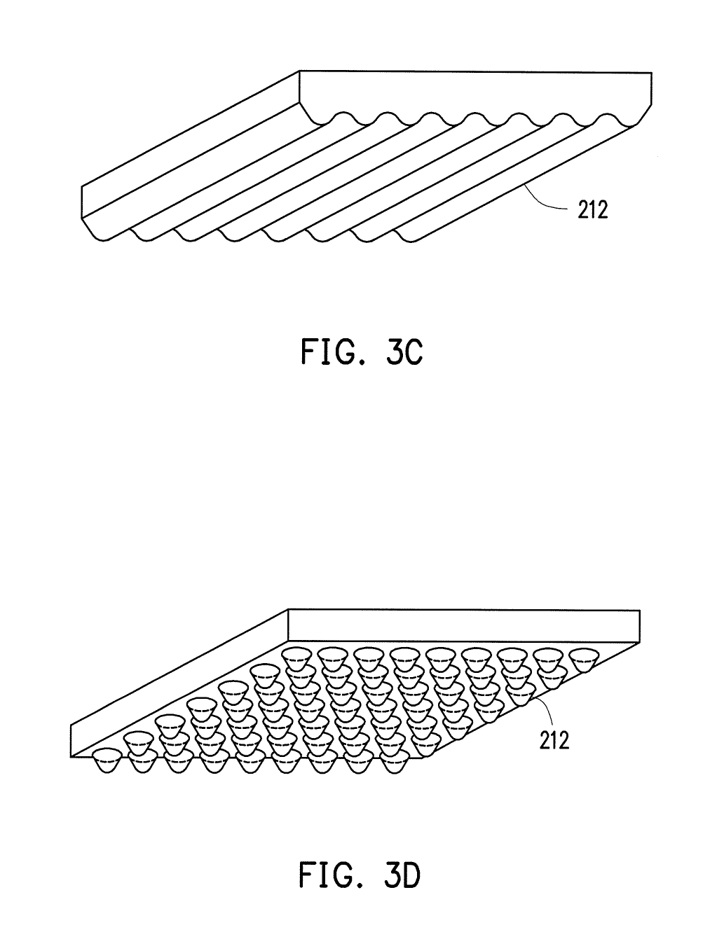

In the first exemplary embodiment, the third encapsulant 210 having the embossing interface 212 may have an embossing surface of different patterns, as that shown in FIG. 3A-FIG. 3D, though the disclosure is not limited thereto.

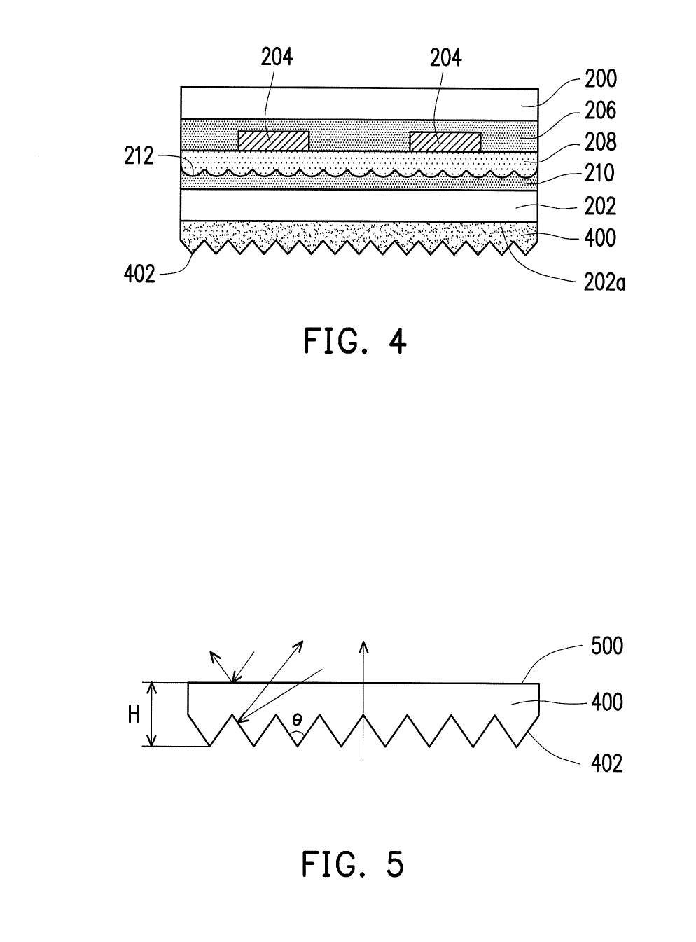

FIG. 4 is a cross-sectional view of a package structure of a solar photovoltaic module according to a second exemplary embodiment, in which the same reference numerals as that of the first exemplary embodiment are used to denote the same or like components.

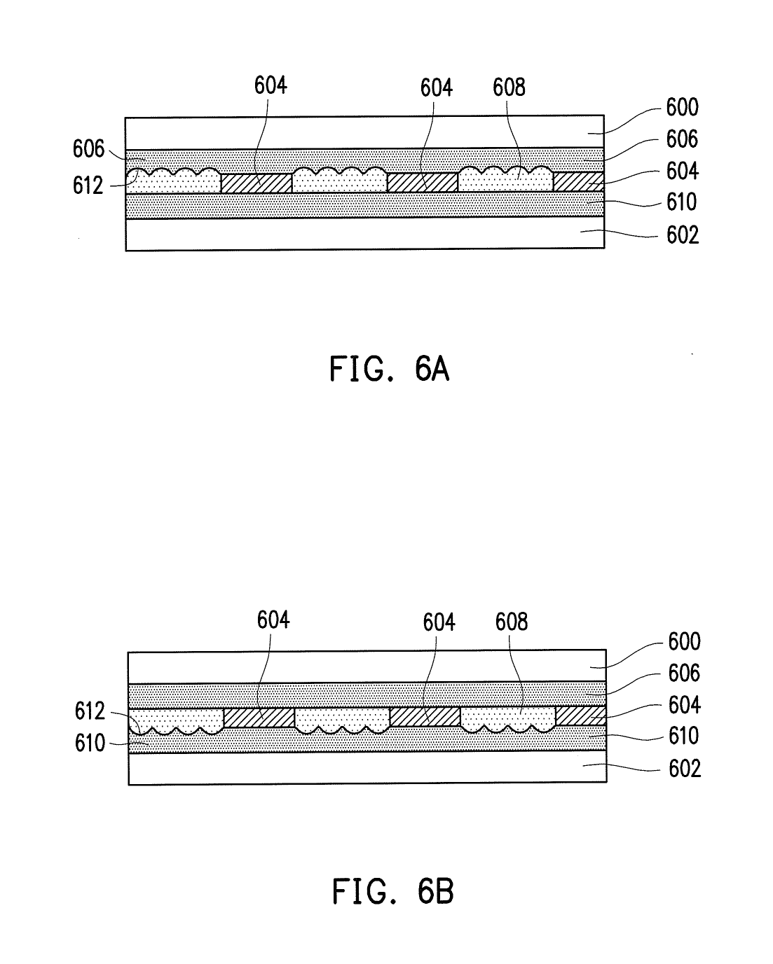

Referring to FIG. 4, an optical board 400 is further disposed on an outer surface 202a of the backsheet 202 of the present exemplary embodiment, where the optical board 400 has an embossing surface 402, the backsheet 202 may be a transparent material, and the optical board 400 may be a transparent material or an opaque material. The other components are the same to that of the first exemplary embodiment. The embossing surface 402 is, for example, a serrated surface, as shown in FIG. 5.

FIG. 5 is an enlarged diagram of the optical board 400 having a plane 500 on one side and the embossing surface 402 on another side, in which arrows represent reflection and transmission status of light entering the optical board 400 along different directions. Structure sizes of the serrated surface (i.e. embossing surface 402) are as follows. A bottom width is 0.05 mm, a period is 0.05 mm, a depth is 0.025 mm, a thickness (height) H of the optical board 400 is 0.4 mm, as shown in FIG. 4. A period of the serrated surface ranges between 10 μm and 2 cm. A vertex angle θ of the serrated surface is greater than 60° and smaller than 90°, where the vertex angle θ represents the embossing surface 402. A material of the optical board 400 is, for example, polyethylene terephthalate (PET), n₁ refractive index range is about 1.6 to 1.7, the refractive index of the optical board 400 has to be higher than that of the external environment, and in the present exemplary embodiment, the external environment is air n₂ with a refractive index of 1. The vertex angle θ has to satisfy a high optical reflection condition, and preferably a total reflection angle from the optically thicker medium n₁ to the optically thinner medium n₂ satisfies θ_{c}≧arcsin(n₂/n₁), where n₁sinθ₁=n₂sinθ₂. Namely, the structure of a front side (i.e. the optical board 400) of the embossing surface 402 of FIG. 5 has a higher refractive index than that of a backside (for example, air) of the embossing surface 402, so as to achieve a high reflection mechanism.

FIG. 6A is a cross-sectional view of a package structure of a solar photovoltaic module according to a third exemplary embodiment of the disclosure.

Referring to FIG. 6, the package structure of the solar photovoltaic module of the third exemplary embodiment includes a transparent substrate 600, a backsheet 602 disposed opposite to the transparent substrate 600, a plurality of solar cells 604 between the transparent substrate 600 and the backsheet 602, and a first encapsulant 606, a second encapsulant 608 and a third encapsulant 610 sandwiched between the transparent substrate 600 and the backsheet 602. An embossing interface 612 exists between the first encapsulant 606 and the second encapsulant 608, and the first encapsulant 606 having the embossing interface 612 is a thermosetting material, for example, EVA or PVB. Moreover, the encapsulants 606, 608 and 610 may be color package materials. Shapes of the embossing interface 612 and a material of the backsheet 602 are as that described in the aforementioned embodiment.

FIG. 6B is a cross-sectional view of another package structure of a solar photovoltaic module according to the third exemplary embodiment of the disclosure, in which the same reference numerals as that of FIG. 6A are used to denote the same or similar components. In FIG. 6B, the embossing interface 612 is located between the second encapsulant 608 and the third encapsulant 610. When a refractive index of the second encapsulant 608 is greater than that of the third encapsulant 610, the reflection effect of the embossing interface 612 is enhanced.

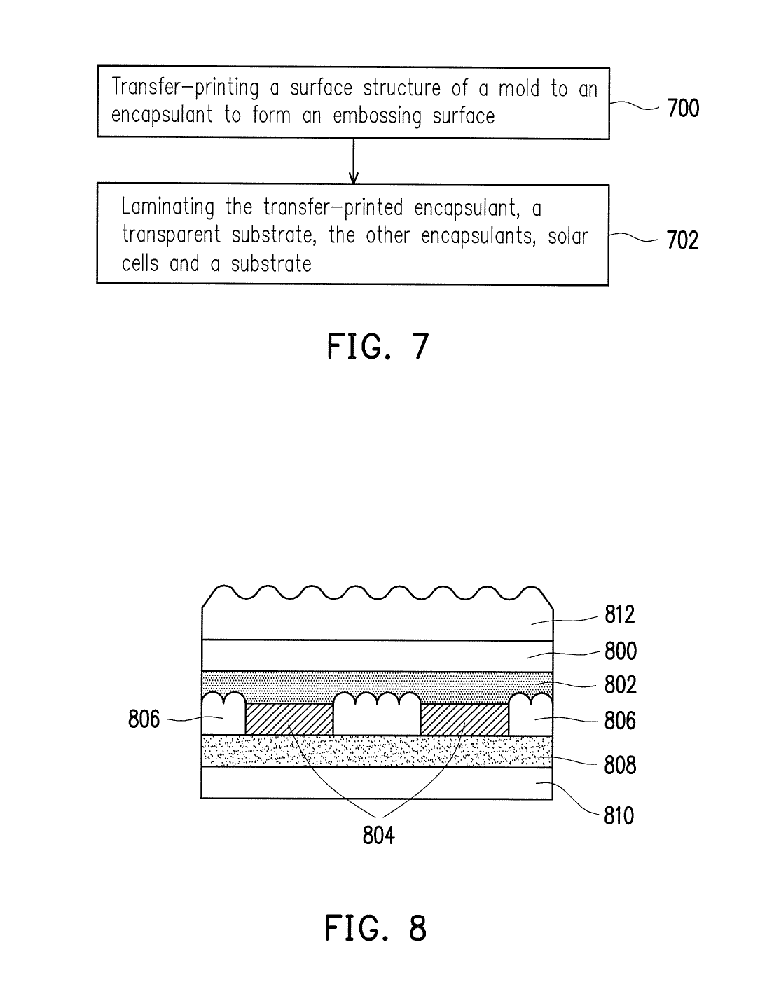

FIG. 7 is a flowchart illustrating a method of manufacturing a package structure of a solar photovoltaic module according to a fourth embodiment of the disclosure.

Referring to FIG. 7, in step 700, a surface structure of a mold is transfer-printed to an encapsulant to form an embossing surface, where the encapsulant having the embossing surface is a thermosetting material, for example, EVA or PVB, etc. In this case, a temperature of the mold is higher than a melting temperature of the encapsulant to be transfer-printed, so as to soften the encapsulant to print the required embossing surface thereon. The surface structure of the mold is, for example, a serrated structure having a linear, a quadratic or multiple approximation curvature surface, so as to print the embossing surface as that shown in FIG. 3A-FIG. 3D.

In step 702, the transfer-printed encapsulant, a transparent substrate, other encapsulants, a plurality of solar cells between the encapsulants and a substrate are laminated. The step 702 may be implemented by using existing equipments and lamination process, so that a detailed description thereof is not repeated.

Several experiment results are provided below to verify the effects of the disclosure.

### Comparison Example

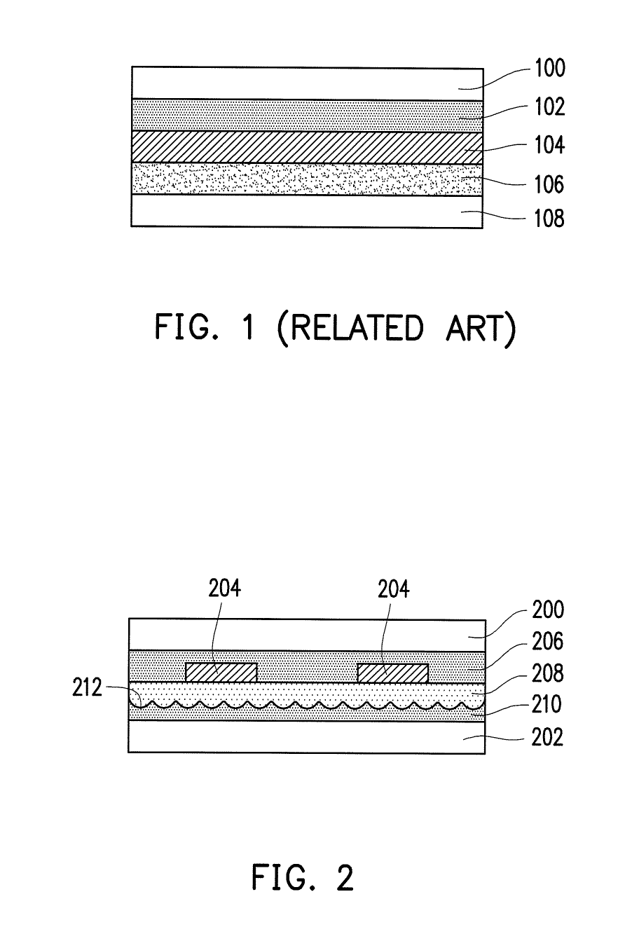

A general package structure of a transparent solar photovoltaic module of FIG. 1 is manufactured according to an existing lamination process, by which a structure of the glass/the EVA adhesive/a 6-inch single-crystalline solar photovoltaic module/the EVA adhesive/the glass is put into a lamination machine. Then, under a temperature of 165.0° C., an upper chamber and a lower chamber are vacuum-pumped by a pressure of 10⁻² torr for 8 minutes, and then the vacuum of the upper chamber is broken for 8 minutes to complete laminating the module package.

An “A class” flash simulator of IEC61215 standard test conditions (STC) is used to test a voltage-current output characteristic of output power, and package of the 6-inch single-crystalline solar cells is used as a comparison reference, the module output power is 3.44 W, and 0% enhancement of the module output power is defined as an comparison experiment.

### First Experiment

The package structure of the solar photovoltaic module of FIG. 6A is manufactured according to the fabrication process of the comparison example, which has a structure of the glass/the EVA adhesive/the EVA adhesive with an embossing interface between the solar cells/the single-crystalline solar cells/the EVA adhesive/the PET backsheet. The embossing interface is an embossing glass, which has a bottom width of about 0.1 mm, a period of about 1 mm, and a height of about 0.1 mm. Then, a first fabrication process is performed to laminate a structure of the glass/the EVA adhesive (the EVA adhesive having the embossing interface between the solar cells), and under the temperature of 165.0° C., the upper chamber and the lower chamber are vacuum-pumped by the pressure of 10⁻² torr for 8 minutes, and then the vacuum of the upper chamber is broken for 8 minutes to complete the first lamination process of the embossing interface. Then, a second fabrication process is performed to complete laminating the module package, and fabrication parameters thereof are the same to that of the first lamination process. The EVA adhesive 608 and the EVA adhesive 610 have the same material, and according to the IEC61215 standard test conditions, the output power is tested according to the same method as that of the comparison example. By comparing the voltage-current output characteristics of the comparison example and the first experiment, it is discovered that the module power can be enhanced by 0.77%.

### Second Experiment

The package structure of the solar photovoltaic module of FIG. 6B is manufactured according to the fabrication process of the comparison example, which has a structure of the glass 600/the EVA adhesive 606/the single-crystalline solar cells 604/the EVA adhesive 608 with an embossing interface between the solar cells/the EVA adhesive 610/the PET backsheet 602. Fabrication of the embossing interface is the same as that of the first experiment, and after the first fabrication process, a structure of the glass 600/the EVA adhesive 606/the single-crystalline solar cells 604/the EVA adhesive 608 with the embossing interface between the solar cells is laminated, where the embossing interface is located between the encapsulant 608 and the encapsulant 610. The EVA adhesive 608 and the EVA adhesive 606 have the same material, and the embossing structure also has a bottom width of about 0.1 mm, a period of about 1 mm, and a height of about 0.1 mm. Then, the second fabrication process is performed to complete laminating the module package, and the output power is tested according to the same method as that of the comparison example. By comparing the voltage-current output characteristics of the comparison example and the second experiment, it is discovered that the module power can be enhanced by 0.96%.

### Third Experiment

The package structure of the solar photovoltaic module of FIG. 2 is manufactured according to the fabrication process of the comparison example, which has a structure of the glass 202/the EVA adhesive 206/the single-crystalline solar cells 204/the EVA adhesive 208 with an embossing interface/the EVA adhesive 210/the PET backsheet 202. Fabrication of the embossing interface is the same as that of the first experiment, and after the first fabrication process, a structure of the glass 202/the EVA adhesive 206/the single-crystalline solar cells 204/the EVA adhesive 208 with an embossing interface between the solar cells is laminated, where the embossing interface is located between the encapsulant 208 and the encapsulant EVA adhesive 210, and the embossing structure also has a bottom width of about 0.1 mm, a period of about 1 mm, and a height of about 0.1 mm. Then, the second fabrication process is performed to complete laminating the module package, and the output power is tested according to the same method as that of the comparison example. By comparing the voltage-current output characteristics of the comparison example and the third experiment, it is discovered that the module power can be enhanced by 0.83%.

### Fourth Experiment

The package structure of the solar photovoltaic module of FIG. 4 is manufactured according to the fabrication process of the comparison example, which has a structure of the glass 202/the EVA adhesive 206/the single-crystalline solar cells 204/the EVA adhesive 208 with an embossing interface/the EVA adhesive 210/the PET backsheet 202/the optical board 400. Regarding the fabrication method of the embossing interface, after the first fabrication process, a structure of the EVA adhesive 208 with the embossing interface/the EVA adhesive 210/the PET backsheet 202/the optical board 400 is laminated, and the embossing structure also has a bottom width of about 0.1 mm, a period of about 1 mm, and a height of about 0.1 mm. Then, the second fabrication process is performed to complete laminating the module package, where the encapsulant EVA adhesive 208 and the encapsulant EVA adhesive 206 have the same material. Then, the output power is tested according to the same method as that of the comparison example. By comparing the voltage-current output characteristics of the comparison example and the fourth experiment, it is discovered that the module power can be enhanced by 1.02%.

### Fifth Experiment

A package structure of a solar photovoltaic module of FIG. 8 is manufactured according to the fabrication process of the comparison example, which has a structure of a glass 800/an EVA adhesive 802 with an embossing interface/single-crystalline solar cells 804/an EVA adhesive 806/an EVA adhesive 808/a PET backsheet 810, and an optical board 812 added on the glass 800. The EVA adhesive 802 with the embossing interface is fabricated by transfer-printing an embossing glass mold, and the structure thereof has a bottom width of about 0.1 mm, a period of about 1 mm, and a height of about 0.1 mm. After the first fabrication process, a structure of the optical board 812/the glass 800/the EVA adhesive 802 with the embossing interface is laminated, where the embossing interface is located between the solar cells 804 and the encapsulant 802, and the embossing structure also has a bottom width of about 0.1 mm, a period of about 1 mm, and a height of about 0.1 mm. Then, the second fabrication process is performed to complete laminating the module package. Then, the output power is tested according to the same method as that of the comparison example. By comparing the voltage-current output characteristics of the comparison example and the fifth experiment, it is discovered that the module power can be enhanced by 2.34%.

### Sixth Experiment

Similar to the fifth experiment, the package structure of the solar photovoltaic module of FIG. 8 is manufactured according to the fabrication process of the comparison example, where the optical board 812 can be transfer-printed with the EVA adhesive with the embossing interface for substitution, and transfer-printing of an embossing glass mold of the EVA adhesive 802 is also performed, and both structures thereof have a bottom width of about 0.1 mm, a period of about 1 mm, and a height of about 0.1 mm. After the first fabrication process, a structure of the optical board 812 with the embossing interface/the glass 800/the EVA adhesive 802 with the embossing interface is laminated, where the embossing interface is located between the solar cells 604 and the encapsulant 610, and the embossing structure also has a bottom width of about 0.1 mm, a period of about 1 mm, and a height of about 0.1 mm. Then, the second fabrication process is performed to complete laminating the module package. Then, the output power is tested according to the same method as that of the comparison example. By comparing the voltage-current output characteristics of the comparison example and the sixth experiment, it is discovered that the module power can be enhanced by 1.38%.

### Seventh Experiment

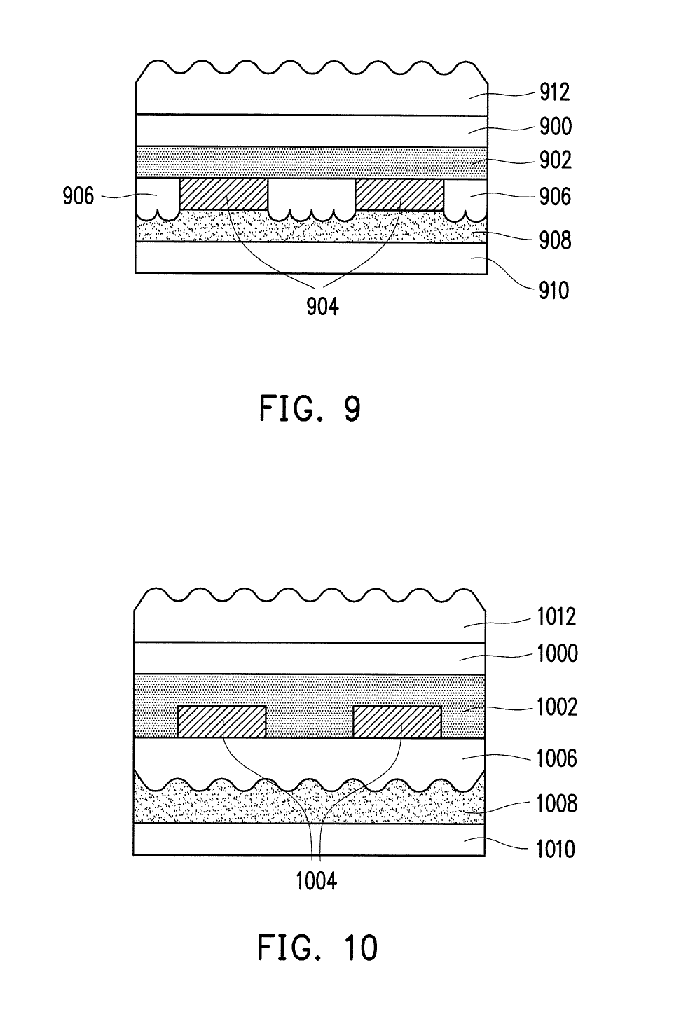

A package structure of a solar photovoltaic module of FIG. 9 is manufactured according to the fabrication process of the comparison example, which has a structure of a glass 900/an EVA adhesive 902/single-crystalline solar cells 904/an EVA adhesive 906/an EVA adhesive 908 with an embossing interface/a PET backsheet 910, and an optical board 912 is added on the glass 900. The optical board 912 and the EVA adhesive 908 with the embossing interface are all fabricated by transfer-printing an embossing glass mold, and structures thereof has a bottom width of about 0.1 mm, a period of about 1 mm, and a height of about 0.1 mm. After the first fabrication process, a structure of the optical board 912 with the embossing interface/the glass 900/the EVA adhesive 902/the single-crystalline solar cells 904/the EVA adhesive 906/the EVA adhesive 908 with the embossing interface is laminated, where the embossing interface is located between the solar cells 904 and the encapsulant 908, the EVA adhesive 906 and the EVA adhesive 908 have the same material, and the embossing structure also has a bottom width of about 0.1 mm, a period of about 1 mm, and a height of about 0.1 mm. Then, the second fabrication process is performed to complete laminating the module package. Then, the output power is tested according to the same method as that of the comparison example. By comparing the voltage-current output characteristics of the comparison example and the seventh experiment, it is discovered that the module power can be enhanced by 1.68%.

### Eighth Experiment

A package structure of a solar photovoltaic module of FIG. 10 is manufactured according to the fabrication process of the comparison example, which has a structure of a glass 1000/an EVA adhesive 1002/6-inch single-crystalline solar cells 1004/an EVA adhesive 1006 with an embossing interface/an EVA adhesive 1008/a PET backsheet 1010, and an optical board 1012 is added on the glass 1000. After the first fabrication process, a structure of the optical board 1012/the glass 1000/the EVA adhesive 1002/the 6-inch single-crystalline solar cells 1004/the EVA adhesive 1006 with the embossing interface is laminated, where the embossing interface is located between the encapsulant 1006 and the encapsulant EVA adhesive 1008, and the embossing structure also has a bottom width of about 0.1 mm, a period of about 1 mm, and a height of about 0.1 mm. Then, the second fabrication process is performed to complete laminating the module package. Then, the output power is tested according to the same method as that of the comparison example. By comparing the voltage-current output characteristics of the comparison example and the eighth experiment, it is discovered that the module power can be enhanced by 1.57%. In this example, the optical board 1012 can be transfer-printed with the EVA adhesive with the embossing interface for substitution, and transfer-printing of an embossing glass mold of the EVA adhesive 1006 is also performed, and it is discovered that the module power can be enhanced by 0.9%.

### Ninth Experiment

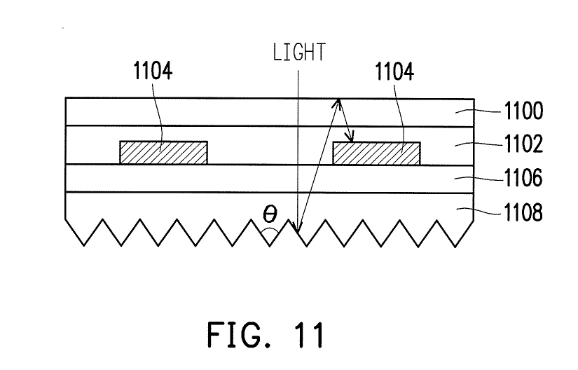

An optical simulation analysis is performed, and the simulated package structure of a solar photovoltaic module is shown in FIG. 11, which has a structure of a glass 1100/an EVA adhesive 1102/6-inch single-crystalline solar cells 1104/a PET backsheet 1106, and an optical board 1108 is on the back of the backsheet 1106. It set vertex angle θ of the optical board 1108 as shown in FIG. 11. When the light is incident to the solar photovoltaic module of FIG. 11, it may be reflected back to the solar cells 1104 through the optical board 1108.

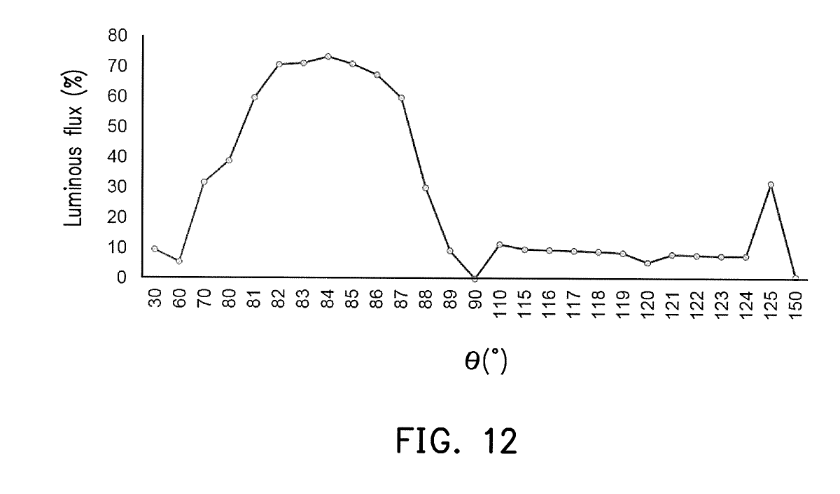

The simulation result shows that the luminous flux has significant improvement if the vertex angle θ is larger than 60° and less than 90° as shown in FIG. 12.

### Tenth Experiment

A series of optical simulation analyses are performed, wherein the simulated package structure is the same as that in FIG. 11, but the backsheet 1106 has different refractive index (n). The refractive index of the backsheet 1106 is 1.4, 1.5, 1.6, 1.7 and 1.8 respectively.

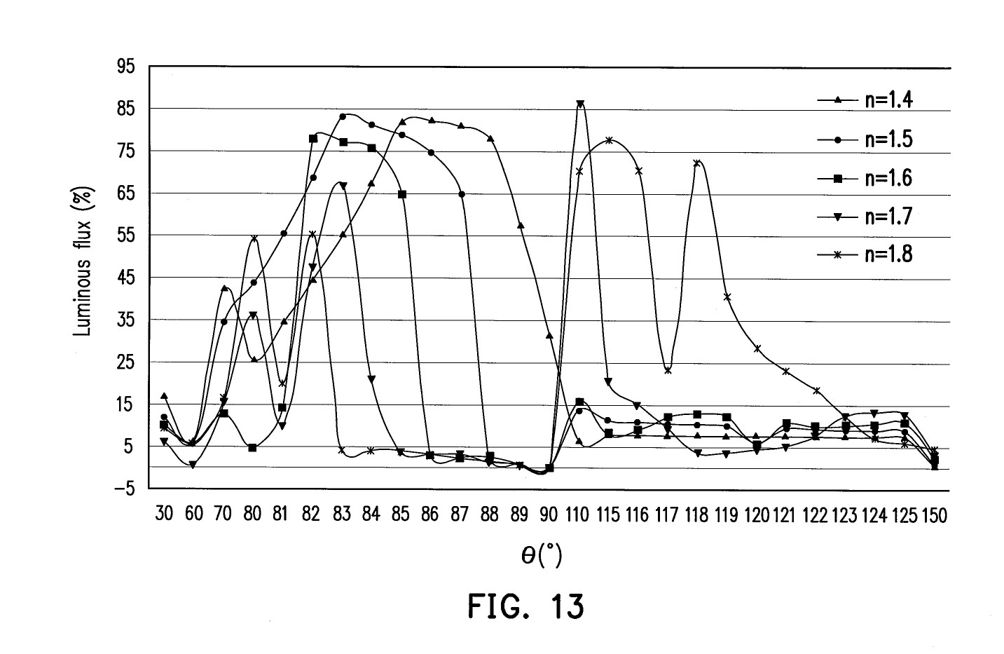

The simulation result shows that the luminous flux has significant improvement in response to different range in the vertex angle θ (i.e. 60°<θ<150°) as shown in FIG. 13. For example, supposing that the refractive index of the backsheet is 1.4 (n=1.4), the luminous flux has significant improvement when the vertex angle θ is larger than 60° and less than 110°. If n=1.5, the luminous flux has significant improvement when the vertex angle θ is larger than 60° and less than 88°. If n=1.6, the luminous flux has significant improvement when the vertex angle θ is larger than 80° and less than 86°. If n=1.7, the luminous flux has significant improvement when the vertex angle θ is larger than 60° and less than 85° or larger than 90° and less than 118°. If n=1.8, the luminous flux has significant improvement when the vertex angle θ is larger than 60° and less than 83° or larger than 90° and less than 124°.

In summary, in the disclosure, an optical board having an embossing surface are applied at back of the solar photovoltaic module, since the embossing surface is a serrated surface with a vertex angle being larger than 60° and less than 150°, the luminous flux may be enhanced so as to improve a light trapping effect.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A package structure of a solar photovoltaic module, comprising:
a transparent substrate;
a backsheet, disposed opposite to the transparent substrate;
a plurality of solar cells, located between the transparent substrate and the backsheet; and
a plurality of encapsulants, sandwiched by the transparent substrate and the backsheet, and encapsulating the solar cells, wherein at least one embossing interface exists between the encapsulants, and the encapsulant having the embossing interface is a thermosetting material; and
an optical board, adhered to an outer surface of the backsheet, wherein the optical board has an embossing surface, and the embossing surface is a serrated surface, and a vertex angle of the serrated surface is larger than 60° and less than 150°.

2. The package structure of the solar photovoltaic module as claimed in claim 1, wherein the backsheet comprises a transparent material.

3. The package structure of the solar photovoltaic module as claimed in claim 1, wherein a structure size and a period of the serrated surface range from 10 μm to 2 cm.

4. The package structure of the solar photovoltaic module as claimed in claim 1, wherein an edge of the serrated surface has a linear, a quadratic or multiple approximation curvature surface.

5. The package structure of the solar photovoltaic module as claimed in claim 1, wherein the encapsulants comprise color package materials.

6. The package structure of the solar photovoltaic module as claimed in claim 1, wherein the backsheet is polyethylene terephthalate (PET) backsheet, and the vertex angle of the serrated surface is larger than 60° and less than 90°.

7. The package structure of the solar photovoltaic module as claimed in claim 1, wherein a refractive index of the backsheet is 1.4, and the vertex angle of the serrated surface is larger than 60° and less than 90°.

8. The package structure of the solar photovoltaic module as claimed in claim 1, wherein a refractive index of the backsheet is 1.5, and the vertex angle of the serrated surface is larger than 60° and less than 88°.

9. The package structure of the solar photovoltaic module as claimed in claim 1, wherein a refractive index of the backsheet is 1.6, and the vertex angle of the serrated surface is larger than 80° and less than 86°.

10. The package structure of the solar photovoltaic module as claimed in claim 1, wherein a refractive index of the backsheet is 1.7, and the vertex angle of the serrated surface has two ranges, in which one is larger than 60° and less than 85° and the other is larger than 90° and less than 118°.

11. The package structure of the solar photovoltaic module as claimed in claim 1, wherein a refractive index of the backsheet is 1.8, and the vertex angle of the serrated surface has two ranges, in which one is larger than 60° and less than 83° and the other is larger than 90° and less than 124°.
